(19) United States
(12) Patent Application Publication
(10) Pub. No.: US 2013/0322478 A1
(43) Pub. Date: Dec. 5, 2013

(54) Semiconductor Laser Device

(71) Applicant: Hitachi, Ltd., Tokyo (JP)

(72) Inventors: Koichiro ADACHI, Musashino (JP); Hideo ARIMOTO, Kodaira (JP); Shigeki MAKINO, Hitachinaka (JP); Toshiki SUGAWARA, Kokubunji (JP)

(21) Appl. No.: 13/904,856

(22) Filed: May 29, 2013

(30) Foreign Application Priority Data
May 31, 2012 (JP) 2012-124934

(51) Int. Cl. H01S 5/34

(52) U.S. Cl. CPC H01S 5/34
USPC 372/45.01

(57) ABSTRACT

Beams of light having wavelengths different from each other are generated in a plurality of light generation portions, the beams of light each generated in the plurality of light generation portions are reflected by a monolithic integrated mirror and are incident to a condenser lens, and emission positions on the condenser lens of the beams of light each generated in the plurality of light generation portions deviate from a central position of the condenser lens by a predetermined amount.

This application claims the priority of Japanese Patent Application No. JP 2012-124934, filed May 31, 2012, the disclosure of which is expressly incorporated by reference herein in its entirety.

### BACKGROUND OF THE INVENTION

1. Field of the Invention

The present invention relates to a surface-emitting type semiconductor laser device, particularly, to a technique that is effectively applied to a semiconductor laser element used for an optical communication, and an optical communication module using the same.

2. Background Art

In recent years, a throughput per device of a high-end router has reached 1.6 Tbps, and further increased capacity is predicted in the future. Along with this, in a data transmission of an extremely short distance such as in transmission between devices (several m to several hundreds of m) or in transmission within a device (several cm to 1 m), in order to effectively process the high-capacity data, optically converting the wiring to an optical interconnect is promising. This is because speeding-up of a speed per channel and increase in channel density can be realized at a lower cost by the use of optical transmission, compared to electrical transmission.

In such an optical interconnect, mainly, a parallel method of using a plurality of beams of light of a single wavelength has been considered. However, in the case of the parallel method, along with an increase in communication capacity, from the viewpoint of an optical fiber and a connector mounting area integrating the same, there is a concern about reaching a physical limit in a near future. For example, in 2020, it is expected that the throughput per device of a high-end router will be a grade of 100 Tbps, and at this time, when the speed per channel is set to 25 Gbps, the number of the optical fibers required for each board rises to a large number of approximately 1,000 in the total of the transmission and the reception.

Meanwhile, generally, a size of a communication device such as a server and a router is based on standards defined by the U.S. Energy Information Administration (EIA), and a board width has a size suitable for a rack of 19 inches. For this reason, when using a standard optical interconnect while considering an area of a cooling air hole, an upper limit of the optical fibers capable of being mounted per one board is approximately 300, and 1,000 optical fibers cannot be accommodated.

Thus, as a technique of breaking through such a physical limit, there has been a need for introduction of wavelength division multiplexing (WDM) to the optical interconnect. Since WDM transmits a plurality of wavelengths by one optical fiber, the number of the optical fibers can be reduced. For example, in the case of the above-mentioned high-end router of 100 Tbps, the number of the optical fibers can be reduced to approximately 130 by the use of the WDM of 8 wavelengths.

WDM has been already introduced into a long-distance optical communication. FIG. 27 is a theoretical view of a WDM transmission light source applied to an optical communication module for 100 GbE for a transmission distance of 10 km and 40 km. Laser diodes 109, 110, 111 and 112 are lasers that each oscillate at a single wavelength, the oscillation wavelengths of each of the laser diodes 109, 110, 111 and 112 are 1310 nm, 1305 nm, 1300 nm, and 1295 nm matched to a wavelength band of a LAN (Local Area Network)-WDM. Respective wavelength selection filters 103, 104, 105 and 106 are filters that cause the wavelengths of 1310 nm or more, 1305 nm or more, 1300 nm or more, and 1295 nm or more to be transmitted therethrough, and reflect the wavelengths shorter than these wavelengths. Thus, for example, the wavelength selection filter 105 causes the light emitted from the laser diode 111 to be transmitted therethrough, but reflects the light emitted from the laser diode 112.

That is, in a wavelength multiplexer that adopts a WDM transmission light source shown in FIG. 27, the light emitted from the laser diodes 109, 110, 111 and 112 is incident to a wavelength multiplexing element constituted by the wavelength selection filters 103, 104, 105 and 106 and the glass substrate 107 via a collimator lens 108 placed on the emission side. In addition, the multiplexed laser beam 113 is condensed on a condenser lens 102 and a Single Mode Fiber (SMF) 101.

Meanwhile, an example of the wavelength multiplexing intended to realize a high-output light source having a small size and a simple configuration, and an example of multiplexing a plurality of single wavelength beams of light are each disclosed in U.S. Pat. No. 6,718,088 B2 and U.S. Pat. No. 6,995,912 B2. In such examples, a configuration is described in which the beams of light emitted from the plurality of laser diodes become the collimated light by the collimator lens, and are coupled to one optical fiber in the condenser lens.

In U.S. Pat. No. 6,718,088 B2, the plurality of laser diodes, the plurality of collimator lenses or a collimator lens array integrating these components and one condenser lens are used. Although U.S. Pat. No. 6,995,912 B2 has the same optical configuration as the above-mentioned U.S. Pat. No. 6,718,088 B2, a further reduction in the number of components is promoted by integrally molding the plurality of collimator lenses and the condenser lens.

Furthermore, for example, JP-A-9-18423 discloses an example that uses the same optical system as the above-mentioned U.S. Pat. No. 6,718,088 B2 and U.S. Pat. No. 6,995,912 B2, but has a different configuration. In this configuration example, a plurality of surface-type lasers has a monolithically integrated laser array, and in a lens array in which a plurality of lenses is arranged integrally, the beams of light emitted from each surface-type laser are collimated by each lens, and are introduced into the optical fiber by one condenser lens. In such a configuration, since the number of the components can be reduced compared to a case where the lasers are separate, the cost can be reduced.

### SUMMARY OF THE INVENTION

However, in the WDM transmission light source having the above-mentioned configuration shown in FIG. 27, there is a problem in that the module size increases from the viewpoint of a manufacturing system and optical crosstalk of the wavelength selection filters. Particularly, since a board area is limited in the optical interconnect, the miniaturization of the optical module is absolutely essential for the increase in throughput. For example, in the router of 100 Gbps, the mounting area per module is preferably about 1 cm square or less. At present, a transmission module or a reception module of 4 wavelengths using the WDM transmission light source having the above-mentioned configuration shown in FIG. 27 has been already developed, and the mounting area is suitable for almost 1 cm square.

However, when using this configuration, further miniaturization is difficult for the above-mentioned reasons. For this reason, when adopting an integral transmission and reception module, the increase in size thereof cannot be avoided. Furthermore, when setting the wavelength number to 4 wavelengths or more, the size of the module naturally increases. Furthermore, in the WDM transmission light source having the above-mentioned configuration shown in FIG. 27, since there is a need for plural optical positioning works between the laser diode, the collimator lens, the wavelength selection filters and the condenser lens, the WDM transmission light source is disadvantageous from a viewpoint of manufacturing cost.

Meanwhile, in the configuration of the above-mentioned U.S. Pat. No. 6,718,088 B2, since a complex filter is not used, the low cost of the used components is anticipated. However, there is a need for plural optical positioning works between the laser diode, the collimator lenses, the collimator lens array, and the condenser lens. Furthermore, since the collimator lenses are separated from the condenser lens, there is a limit to the miniaturization of the module size and the reduction in the number of the components.

Furthermore, in the above-mentioned configuration of U.S. Pat. No. 6,995,912 B2, although the collimator lenses and the condenser lens are integrated with each other to promote the reduction in the number of the components, the module size is limited for the same reasons.

Furthermore, although the surface-type lasers and the collimator lenses have the integrally molded array structure in the above-mentioned configuration of JP-A-9-18423, there is a need for optical positioning among three of the laser chip, the collimator lens array, and the condenser lens. In addition, since the separate lenses are used like cases of the above-mentioned U.S. Pat. No. 6,718,088 B2 and U.S. Pat. No. 6,995,912 B2, problems also remain in the miniaturization.

An object of the invention is to provide a wavelength multiplexing light source that realizes the miniaturization and the cost reduction, and a wavelength multiplexing optical module using the same.

The above-mentioned and other objects and new characteristics of the invention will be clarified from the description of the present specification and the attached drawings.

Among the inventions disclosed in the invention, a representative example will be briefly described.

According to this example, there is provided a semiconductor laser that has a plurality of light generation portions, a light emitting end portion, and a plurality of waveguides formed between the plurality of light generation portions and the light emitting end portion. Each of the plurality of light generation portions includes an n-type InP substrate, an InGaAlAs active layer formed on a surface of the n-type InP substrate, a diffraction grating formed on the InGaAlAs active layer, and a p-type cladding layer formed on the InGaAlAs active layer so as to cover the diffraction grating. Furthermore, the light emitting end portion includes a reflecting mirror for emitting the beams of light each generated in the plurality of light generation portions to a back of the n-type InP substrate, and a condenser lens provided on the back of the n-type InP substrate. Moreover, the wavelengths of beams of light each generated in the plurality of light generation portions are different from each other, the beams of light each generated in the plurality of light generation portions are reflected by the reflecting mirror and are incident to the condenser lens, and the emission positions of the beams of light on the condenser lens each generated in the plurality of light generation portions are shifted from a central position of the condenser lens by a predetermined amount.

Among the inventions disclosed in this application, a representative example obtained by one embodiment will be described as follows.

It is possible to provide the wavelength multiplexing light source that realizes the miniaturization and the cost reduction. In addition, it is possible to provide the wavelength multiplexing optical module that uses the wavelength multiplexing light source.

### BRIEF DESCRIPTION OF THE DRAWINGS

FIG. 1 is a bird's-eye view of a surface side of a multi-wavelength horizontal resonator surface-emitting type laser according to Embodiment 1 of the invention.

FIG. 2 is a bird's-eye view of a light emitting surface side (a back side) of the multi-wavelength horizontal resonator surface-emitting type laser according to Embodiment 1 of the invention.

FIG. 3 is a cross-sectional view of major parts (a cross-sectional view of major parts along line A-A′ of FIG. 1) along an optical axis direction of the multi-wavelength horizontal resonator surface-emitting type laser according to Embodiment 1 of the invention.

FIG. 4A is a principle view of an optical configuration of a case of using a separate glass lens, and FIG. 4B is a principle view of the optical configuration according to Embodiment 1 of the invention.

FIG. 5 is a cross-sectional view of major parts (a cross-sectional view of major parts along line A-A′ of FIG. 1) along the optical axial direction of the multi-wavelength horizontal resonator surface-emitting type laser that shows a manufacturing process of the multi-wavelength horizontal resonator surface-emitting type laser according to Embodiment 1 of the invention.

FIG. 6 is a cross-sectional view of major parts of the same location as FIG. 5 during a manufacturing process of the multi-wavelength horizontal resonator surface-emitting type laser continued from FIG. 5.

FIG. 7 is a cross-sectional view of major parts of the same location as FIG. 5 during a manufacturing process of the multi-wavelength horizontal resonator surface-emitting type laser continued from FIG. 6.

FIG. 8 is a cross-sectional view of major parts of the same location as FIG. 5 during a manufacturing process of the multi-wavelength horizontal resonator surface-emitting type laser continued from FIG. 7.

FIG. 9 is a cross-sectional view of major parts of the same location as FIG. 5 during a manufacturing process of the multi-wavelength horizontal resonator surface-emitting type laser continued from FIG. 8.

FIG. 10 is a cross-sectional view of major parts of the same location as FIG. 5 during a manufacturing process of the multi-wavelength horizontal resonator surface-emitting type laser continued from FIG. 9.

FIG. 11 is a cross-sectional view of major parts of the same location as FIG. 5 during a manufacturing process of the multi-wavelength horizontal resonator surface-emitting type laser continued from FIG. 10.

FIG. 12 is a cross-sectional view of major parts of the same location as FIG. 5 during a manufacturing process of the multi-wavelength horizontal resonator surface-emitting type laser continued from FIG. 11.

FIG. 13 is a cross-sectional view of major parts of the same location as FIG. 5 during a manufacturing process of the multi-wavelength horizontal resonator surface-emitting type laser continued from FIG. 12.

FIG. 14 is a cross-sectional view of major parts of the same location as FIG. 5 during a manufacturing process of the multi-wavelength horizontal resonator surface-emitting type laser continued from FIG. 13.

FIG. 15 is a cross-sectional view of major parts of the same location as FIG. 5 during a manufacturing process of the multi-wavelength horizontal resonator surface-emitting type laser continued from FIG. 14.

FIG. 16 is a bird's-eye view of a small module to which the multi-wavelength horizontal resonator surface-emitting type laser according to Embodiment 1 of the invention is applied.

FIG. 17 is a cross-sectional view of major parts along the optical axial direction of the small module to which the multi-wavelength horizontal resonator surface-emitting type laser according to Embodiment 1 of the invention is applied.

FIG. 18 is a bird's-eye view of a surface side of a multi-wavelength horizontal resonator surface-emitting type laser according to Embodiment 2 of the invention.

FIG. 19 is a bird's-eye view of a light emitting surface side (a back side) of the multi-wavelength horizontal resonator surface-emitting type laser according to Embodiment 2 of the invention.

FIG. 20 is a bird's-eye view of a surface side of a multi-wavelength horizontal resonator surface-emitting type laser that uses a transmission type diffraction grating according to Embodiment 3 of the invention.

FIG. 21 is a bird's-eye view of the light emitting surface side (the back side) of the multi-wavelength horizontal resonator surface-emitting type laser that uses the transmission type diffraction grating according to Embodiment 3 of the invention.

FIG. 22 is a bird's-eye view of the light emitting surface side (the back side) of the multi-wavelength horizontal resonator surface-emitting type laser that uses the reflection type diffraction grating according to Embodiment 3 of the invention.

FIG. 23 is a cross-sectional view of major parts (a cross-sectional view along line B-B′ of FIG. 22) along the optical axial direction of the multi-wavelength horizontal resonator surface-emitting type laser that uses the reflection type diffraction grating according to Embodiment 3 of the invention.

FIG. 24 is a bird's-eye view of a surface side of a multi-wavelength horizontal resonator surface-emitting type laser according to Embodiment 4 of the invention.

FIG. 25 is a bird's-eye view of a surface side of a multi-wavelength horizontal resonator surface-emitting type laser according to Embodiment 5 of the invention.

FIG. 26 is a bird's-eye view of the light emitting surface side (the back side) of the multi-wavelength horizontal resonator surface-emitting type laser according to Embodiment 5 of the invention.

FIG. 27 is a principle view of a WDM transmission light source that is applied to an optical communication module reviewed by the inventors or the like before the invention.

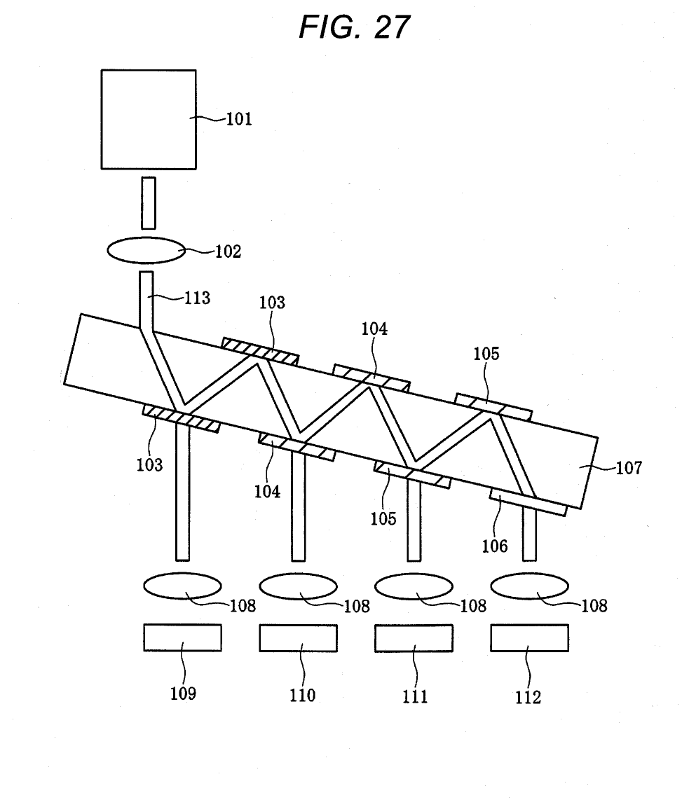

### DESCRIPTION OF EMBODIMENTS

In the flowing embodiments, although the description will be made by being divided into a plurality of sections or embodiments when it is necessary for convenience, except for a case of particularly clarifying otherwise, these are not unrelated to each other, and one is related to a modified example, details, a supplementary description or the like of a part or all of the other.

Furthermore, in the following embodiments, when referring to the number or the like of the elements (including the number, a numerical value, an amount, a range or the like), except for a case of particularly clarifying, a case of being theoretically clearly limited to a specific number or the like, the specific number is not limited, but the number may be the specific number or more or less. In addition, in the following embodiments, it is needless to say that, the components (also including an element step or the like) are not necessarily essential, except for a case of particularly clarifying, a case in which it is considered that the components are theoretically clearly essential or the like. Similarly, in the following embodiments, when referring to shapes, a positional relationship or the like of the components, substantially, shapes approximate to or similar to the shapes or the like are included, except for a case of particularly clarifying, a case in which it is considered that the shapes are theoretically similar or the like. This is also true for the above-mentioned numerical values and ranges.

Furthermore, in the following embodiments, the optical axial direction refers to a direction advancing from the light generation portion (the laser portion) of the laser chip for generating the light (the laser beam) to the light emitting end portion of the laser chip formed with a monolithic integrated mirror and a monolithic integrated lens for emitting the light.

Furthermore, in the drawings used in the following embodiments, in some cases, hatching may be added so as to allow easy viewing of the drawings even in a plan view. Furthermore, in the entire drawings for describing the following embodiments, the components having the same functions are denoted by the same reference numerals in principle, and the repeated description thereof will be omitted. Hereinafter, the embodiments of the invention will be described in detail based on the drawings.

### Embodiment 1

### Multi-Wavelength Horizontal Resonator Surface-Emitting Type Laser

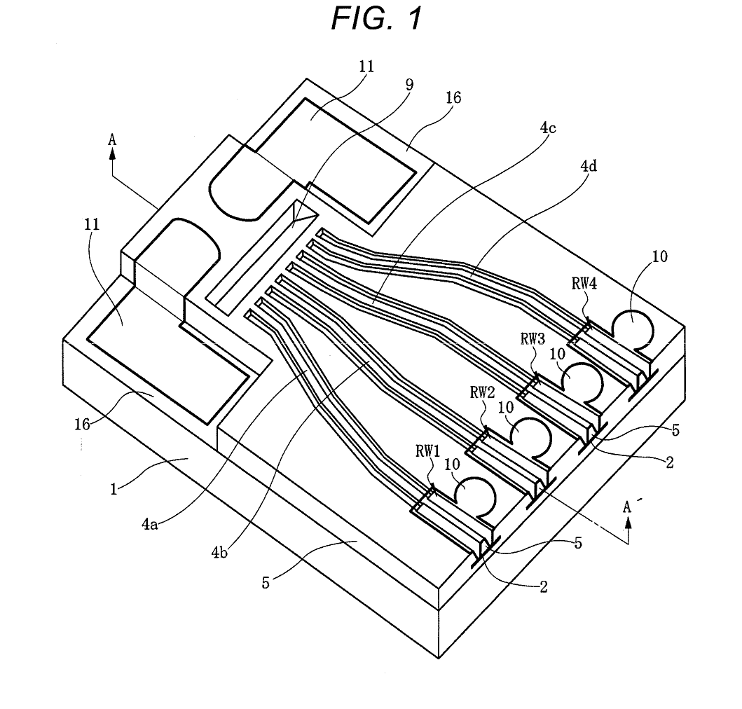

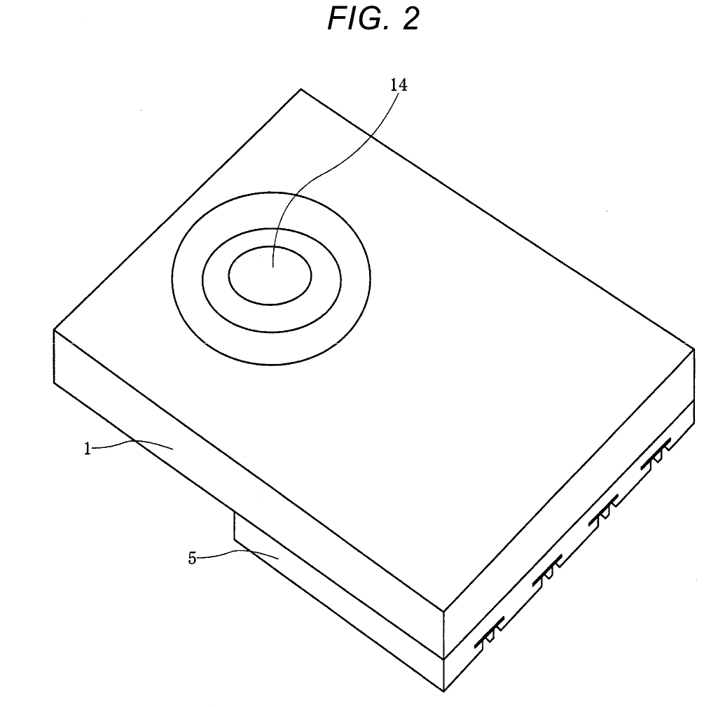

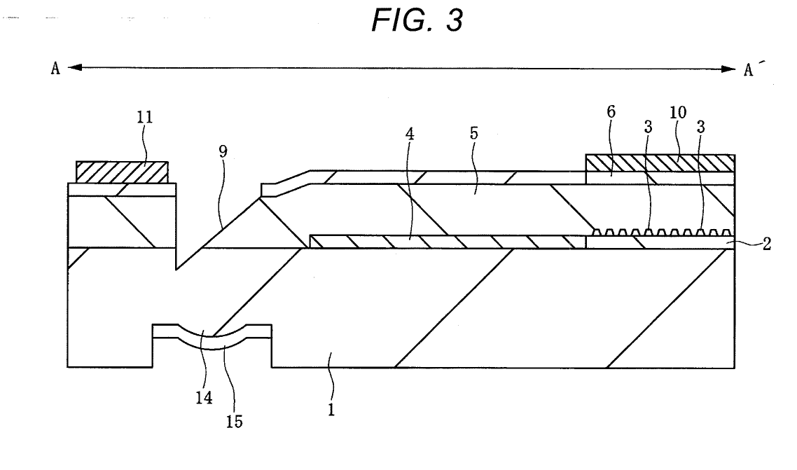

A structure of a multi-wavelength horizontal resonator surface-emitting type laser having a wavelength band of 1.3 μm according to Embodiment 1 will be described using FIGS. 1, 2 and 3. In Embodiment 1, a horizontal resonator surface-emitting type laser of a direct modulation type of 4 channels (a lens integrated horizontal resonator surface-emitting laser of 4 channel array type) will be described as an example. FIG. 1 is a bird's-eye view of the surface side of a multi-wavelength horizontal resonator surface-emitting type laser. FIG. 2 is a bird's-eye view of a light emitting surface side (a back side) of the multi-wavelength horizontal resonator surface-emitting type laser. FIG. 3 is a cross-sectional view of major parts (a cross-sectional view of major parts along line A-A′ of FIG. 1) along the optical axial direction of the multi-wavelength horizontal resonator surface-emitting type laser.

A light generation portion (a laser portion) has an n-type InP (indium phosphide) substrate (semiconductor substrate) 1 that has a surface (a first surface) and a back (a second surface) of an opposite side to the surface, and an InGaAlAs (indium gallium aluminum arsenic) active layer 2 and a p-type InP cladding layer (a semiconductor-embedded layer) 5 are sequentially stacked on the surface of n-type InP substrate 1. Moreover, a shape of a cross-section of the p-type InP cladding layer 5 in a direction perpendicular to the optical axial direction on the surface of the n-type InP substrate 1 has a convex shape in a thickness direction of the n-type InP substrate 1, and is machined in a stripe shape in the optical axial direction. That is, ridge-type waveguide structures RW1, RW2, RW3 and RW4 which are ridge waveguide structures are included.

A pitch interval between the adjacent channels is, for example, 120 μm, and there is an array laser in which four channels are integrated. The multi-wavelength horizontal resonator surface-emitting type laser is a distributed feedback laser including a distributed feedback (DFB) resonator structure in which a diffraction grating 3 is formed directly above the InGaAlAs active layer 2 of each channel along an advancement direction of light. The pitch of the diffraction grating 3 of each channel is designed so as to each oscillate at the different wavelengths at the wavelength band of 1.3 μm. The lengths of the light generation portions (the ridge-type waveguide structures RW1, RW2, RW3 and RW4) in the optical axial direction are, for example, 150 μm in consideration of the high-speed characteristics. Furthermore, the respective channels are electrically separated by separation grooves.

On the ridge-type waveguide structures RW1, RW2, RW3 and RW4 of each channel, a p-type contact layer 6 is formed, and a p-type electrode 10 is formed on the p-type contact layer 6.

Furthermore, the ridge-type waveguide structures RW1, RW2, RW3 and RW4 are butt-joint connected to one of high-mesa type passive waveguides 4a, 4b, 4c and 4d in which InGaAsP is used as the waveguide layer, respectively. A pitch interval of the other light emitting ends of the passive waveguides 4a, 4b, 4c and 4d is, for example, 10 μm. For this reason, the passive waveguides 4a, 4b, 4c and 4d are bending waveguides having a bending portion in a part.

The passive waveguides 4a, 4b, 4c and 4d are waveguides formed by being embedded and grown in a bulk semiconductor, or waveguides constituted by multiple quantum well structures in which two kinds of semiconductor layers or more are stacked in plural numbers. Furthermore, the lengths of the passive waveguides 4a, 4b, 4c and 4d in the optical axial direction are, for example, 500 μm.

In the light emitting end portion, a monolithic integrated mirror (a reflecting mirror) 9 formed by etching a part of the p-type Inp cladding layer 5 and the n-type Inp substrate 1 is provided. Furthermore, in a peripheral portion of the monolithic integrated mirror 9, an n-type contact layer 16 is formed, and an n-type electrode 11 is formed on the surface thereof. Thereby, it is possible to constitute a flip chip structure in which the p-type electrode 10 and the n-type electrode 11 are placed on the surface of the laser chip (a chip formed with the multi-wavelength horizontal resonator surface-emitting type laser). The n-type contact layer 16 is formed by etching a part of the p-type InP cladding layer 5 until the n-type InP substrate 1 is exposed. The length of a region (the light emitting end portion) formed with the monolithic integrated mirror (the reflecting mirror) 9 and the n-type electrode 11 in the optical axial direction is, for example, 150 μm. Furthermore, the length of the laser chip in the optical axial direction is, for example, 800 μm, and a length in a direction perpendicular to the optical axial direction of the laser chip is, for example, 540 μm.

On the back of the n-type InP substrate 1, a concave step is formed, and on the bottom portion of the step, an InP lens (a monolithic integrated lens) 14 formed by etching the n-type InP substrate 1 is formed. Furthermore, on the surface of the InP lens 14, for example, a non-reflective film 15 formed of a thin film of alumina (Al₂O₃) is formed.

### Characteristics of Multi-Wavelength Horizontal Resonator Surface-Emitting Type Laser

In the multi-wavelength horizontal resonator surface-emitting type laser according to Embodiment 1, the laser beams of a plurality of different wavelengths are emitted from one laser chip, and these laser beams can be condensed to an external one point. Thereby, it is possible to perform the wavelength multiplexing, without using a multiplexing device such as a glass substrate with a filter, a collimator lens or a condenser lens.

Furthermore, since the array-type laser can integrate the plurality of laser beams in one chip using the wafer process, the integration of a small size and high-density can be performed, compared to a case of individually performing the hybrid mounting of the plurality of laser chips. Thereby, even when the number of wavelengths is increased, the light source of a small size can be realized.

Thus, the reduction of the number of components and the miniaturization can be performed in the wavelength multiplexing optical module. Furthermore, the optical positioning work required at the time of mounting is only performed between the laser chip and the optical fiber, and the manufacturing cost of the wavelength multiplexing optical module can be reduced.

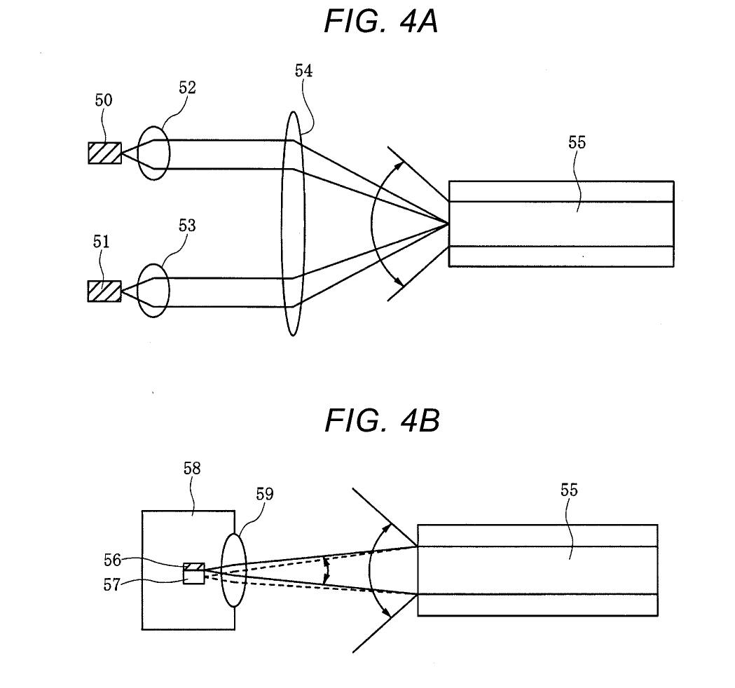

Furthermore, the plurality of laser beams can be multiplexed by a single lens. This principle will be described using FIGS. 4A and 4B. FIG. 4A is a principle view of an optical configuration of a case of using a separate glass lens, and FIG. 4B is a principle view of an optical configuration according to Embodiment 1.

As shown in FIG. 4A, when using the separate glass lens, the laser beams emitted from the laser diodes 50 and 51 each become the parallel beam via the collimator lenses 52 and 53, and then this is condensed on the optical fiber 55 by the condenser lens 54.

A flare angle of beam emitted from a general laser diode is about 20°. For this reason, in order to constrict the beam using the glass lens to a parallel beam or near a parallel beam, a relatively great curvature is required. Meanwhile, when the curvature increases, a condensing action of the glass lens also increases, there is a problem in that NA of the glass lens exceeds NA of the optical fiber or a focal distance of the lens becomes extremely shorter, and thus mounting is difficult. Thus, in an optical system that uses a separate glass lens, there is a need to individually provide the collimator lenses 52 and 53 and the condenser lens 54.

On the contrary, in the optical configuration according to Embodiment 1, as shown in FIG. 4B, since the laser beam emitted from the laser active layers 56 and 57 is distributed through the InP 58, for example, the flare angle can be set to about 6° to 8°. In addition, since a specific refractive index of the glass is about 1.5 and meanwhile the specific refractive index of InP is greater than that at 3.2, even when setting the InP condensing lens 59 to a relatively small curvature, the beam constriction can be easily performed. Furthermore, since the curvature is small, it is possible to reduce a difference in an emitting angle when shifting an optical axis center and a lens center. For this reason, unlike a case of using a separate glass lens, it is possible to concurrently realize the constriction of the flare angle and the condensing of the plurality of laser beams to one point, using one lens.

Thus, according to the Embodiment 1, the wavelength multiplexing optical module of a small size and a low cost can be realized.

### Manufacturing Method of Multi-Wavelength Horizontal Resonator Surface-Emitting Type Laser

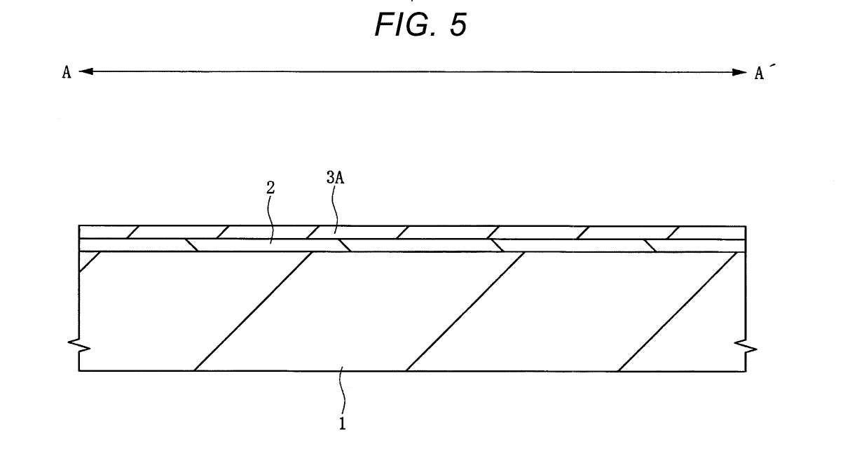

A manufacturing method of a multi-wavelength horizontal resonator surface-emitting type laser according to Embodiment 1 will be described using FIGS. 5 to 15. FIGS. 5 to 15 are cross-sectional views of major parts (a cross-sectional view of major parts along line A-A′ shown in the above-mentioned FIG. 1) of the multi-wavelength horizontal resonator surface-emitting type laser shown in FIGS. 1 to 3 along the optical axial direction. The entire channels can be manufactured together.

First, as shown in FIG. 5, in order to form the structure of the light generation portion (the laser portion), a semiconductor multilayer body is prepared in which the InGaAlAs active layer 2 is formed on the n-type InP substrate 1, and the diffraction grating layer 3A is formed on the InGaAlAs active layer 2. The n-type InP substrate 1 is a thin plate having a substantially circular shape when viewed in a plane called a wafer at this stage, and the thickness thereof is, for example, 400 to 500 μm. Furthermore, for example, the thickness of the InGaAlAs active layer 2 is 0.1 to 0.2 μm. For example, the InGaAlAs active layer 2 is constituted by an optical confinement layer formed of the n-type InGaAlAs, a multiple quantum well layer formed of InGaAlAs, and an optical confinement layer formed of the p-type InGaAlAs. Furthermore, the diffraction grating layer 3A is formed, for example, of an InGaAlsP-based material.

For example, the InGaAlAs active layer 2 includes a multiple quantum well structure in which a well layer having a thickness of 7 nm formed of undoped InGaAlAs and a barrier layer having a thickness of 8 nm formed of undoped InAlAs are stacked in five cycles, between the n-type optical confinement layer formed of the n-type InGaAlAs and the p-type optical confinement layer formed of the p-type InGaAlAs. Such a multiple quantum well structure is designed so that sufficient characteristics can be realized as the laser.

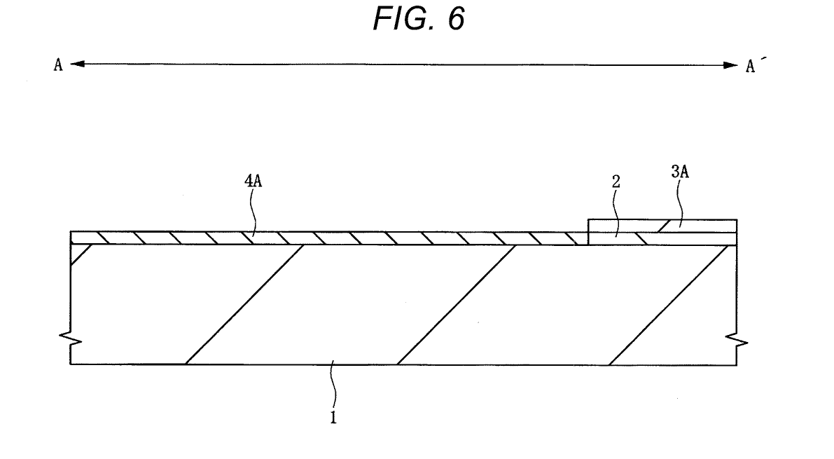

Next, as shown in FIG. 6, the InGaAlAs active layer 2 of the light generation portion and the diffraction grating layer 3A are machined in a stripe pattern (a stripe form), by the wet etching that uses a mask formed of patterned silicon dioxide (SiO₂) film. For example, a width of the stripe pattern in a direction perpendicular to the optical axial direction is 30 μm, and a length thereof in the optical axial direction is, for example, 150 μm. In addition, the InGaAlAs active layer 2 and the diffraction grating layer 3A of a region other than the light generation portion are also removed. For example, sulfuric acid-based etching liquid is used for the wet etching.

Next, a passive waveguide layer 4A constituted by the multiple quantum well structure is formed in which two types or more of the semiconductor layers are stacked in plural in a region other than the light generation portion, by the use of an MOCVD (Metal Organic Chemical Vapor Deposition) method. Otherwise, the bulk semiconductor is grown by being embedded in a region other than the light generation portion, by the use of an MOVPE (Metal Organic Vapor Phase Epitaxy) method, thereby to form the passive waveguide layer 4A.

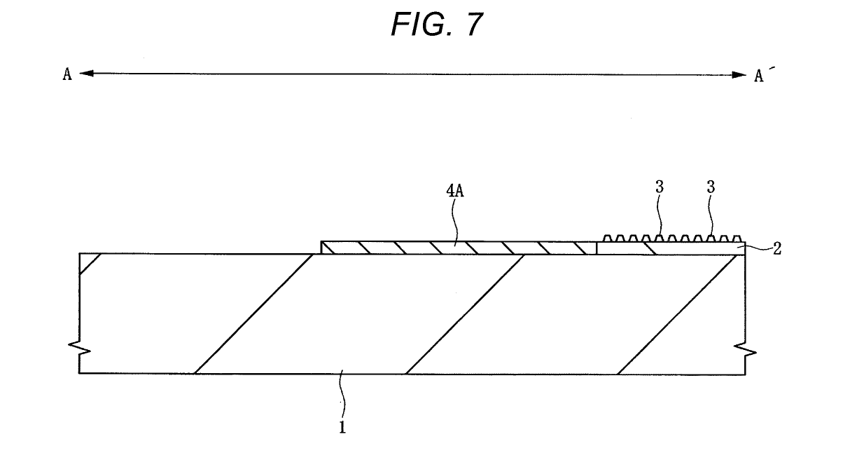

Next, as shown in FIG. 7, the diffraction grating layer 3A is machined by the use of an electron beam exposure method, thereby to form the diffraction grating 3 directly above the InGaAlAs active layer 2 of the light generation portion.

In addition, the passive waveguide layer 4A of the light emitting end portion (a portion emitting the light of an opposite side to the light generation portion when viewed in an advancing direction of the laser beam generated in the light generation portion) is removed by the wet etching or the dry etching. For example, the sulfuric acid-based etching liquid is used for the wet etching. The structure of the diffraction grating 3 is formed so that the oscillation wavelength of the multi-wavelength horizontal resonator surface-emitting type laser at room temperature of each channel is 1295 nm, 1300 nm, 1305 nm and 1310 nm in each channel. In addition, in Embodiment 1, although it has been described that the diffraction grating 3 is uniformly formed in the whole region of the multi-wavelength horizontal resonator surface-emitting type laser, if necessary, a so-called phase shift structure may be provided which is configured by shifting the phase of the diffraction grating 3 in a part of the region. Furthermore, in the Embodiment 1, although the multi-wavelength horizontal resonator surface-emitting type laser is constituted by the DFB laser, the invention is not limited thereto. For example, the multi-wavelength horizontal resonator surface-emitting type laser may be constituted by a distributed Bragg reflector type laser which includes an active layer and a distributed Bragg reflector (DBR) layer connected to one end of the active layer, and constitutes a resonator structure by the active layer and the distributed Bragg reflector layer.

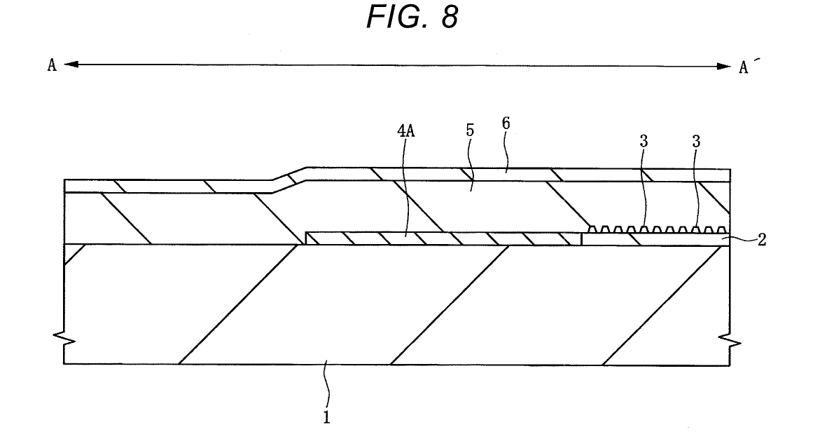

Next, as shown in FIG. 8, the p-type InP cladding layer 5 is formed on the entire surface of the n-type InP substrate 1 so as to cover the diffraction grating 3 and the passive waveguide layer 4A. In addition, the p-type contact layer 6 formed of the p-type InGaAs is formed on the p-type InP cladding layer 5. The carrier concentration due to doping of the p-type contact layer 6 is about 10¹⁸ cm⁻³.

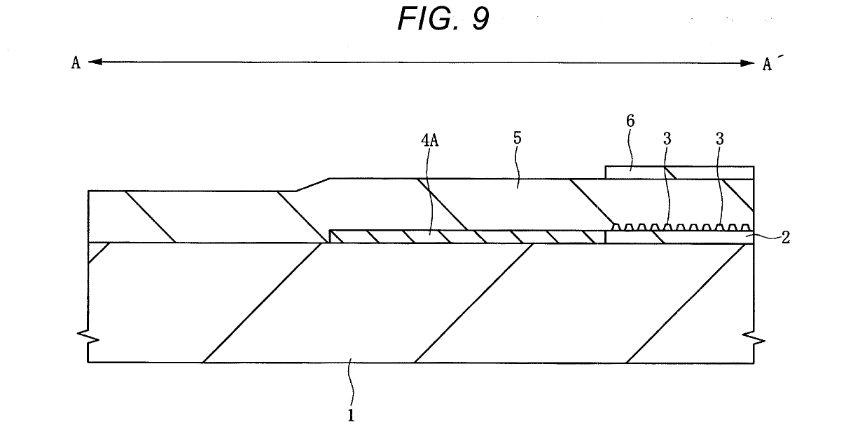

Next, as shown in FIG. 9, the p-type contact layer 6 of the region other than the light generation portion is removed by the wet etching that uses the mask formed of the patterned resist. For example phosphoric acid-based etching liquid is used for the wet etching.

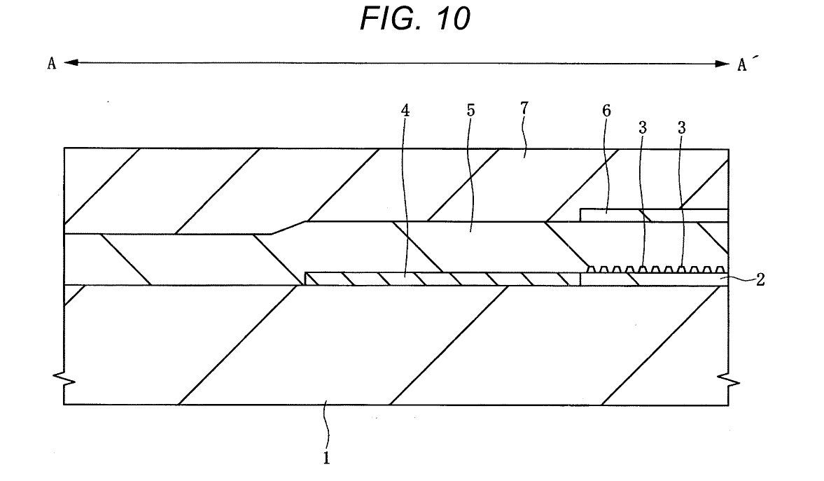

Next, as shown in FIG. 10, a protective mask 7 formed of the patterned silicon dioxide (SiO₂) film is formed. By etching using the protective mask 7, the p-type contact layer 6, the p-type InP cladding layer 5 and the passive waveguide layer 4A are machined, and the ridge-type waveguide structures (the ridge-type waveguide structures RW1, RW2, RW3 and RW4 shown in FIG. 1 mentioned above) and the high-mesa type passive waveguide 4 (the passive waveguides 4a, 4b, 4c and 4d shown in FIG. 1 mentioned above) are each formed. Furthermore, the ridge-type waveguide structures or the like are formed, and at the same time, the p-type InP cladding layer 5 of the region, in which the n-type contact layer is formed in the next process, is also removed.

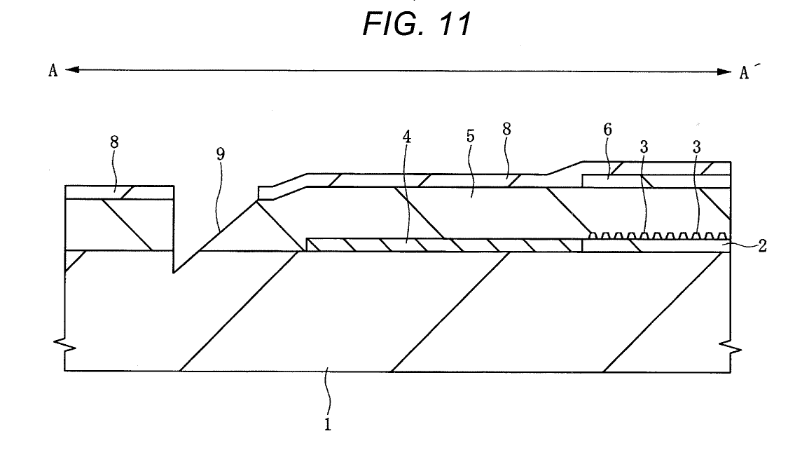

Next, as shown in FIG. 11, after removing the protective mask 7, a protective mask 8 formed of a patterned silicon nitride (SiN) film is formed. By etching a part of the p-type InP cladding layer 5 and the n-type InP substrate 1 of the light emitting end portion to a slope angle of 45° by the use of the protective mask 8, a monolithic integrated mirror (reflecting mirror) 9 is formed. Chemically assisted ion beam etching (CAIBE) using chlorine (Cl) gas and argon (Al) gas is used for the slope etching. By inclining and etching the n-type InP substrate 1 to the angle of 45° by the use of this method, etching of the slope angle of 45° can be realized. In Embodiment 1, although the etching method using CAIBE has been described, reactive ion beam etching (RIBE) of chlorine-based gas or the wet etching may be used. A cross-sectional shape of the monolithic integrated mirror 9 in the optical axial direction may be a “v” shape of katakana, a “V shape” may be used, and a structure only constituted by an inclined surface may be used.

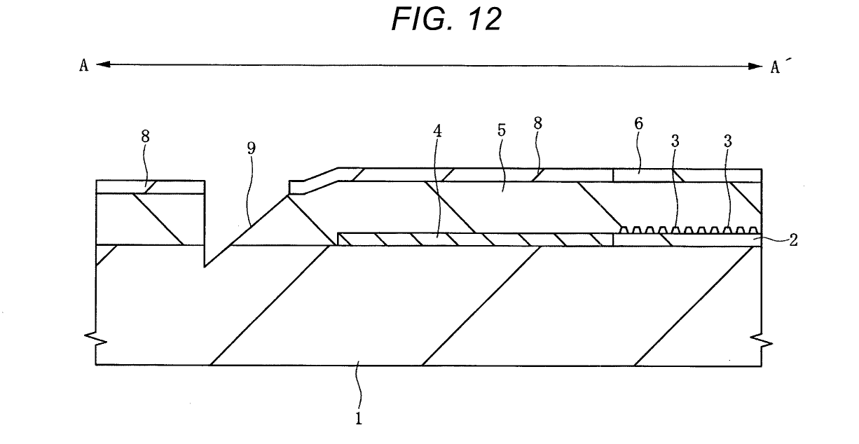

Next, as shown in FIG. 12, the protective mask 8 on the p-type contact layer 6 is removed.

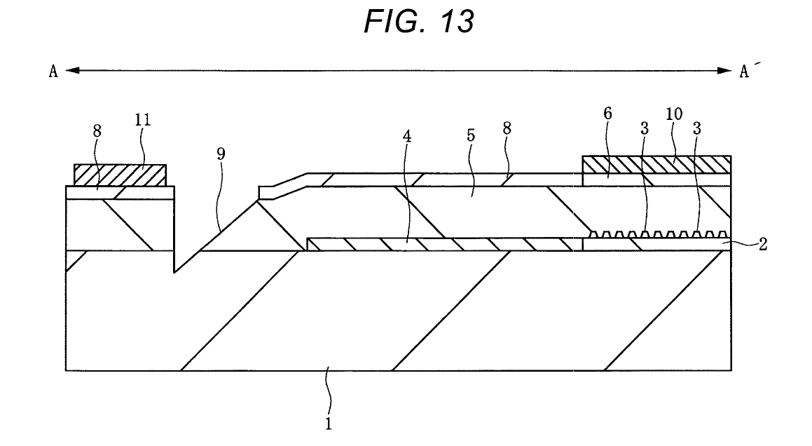

Next, as shown in FIG. 13, a p-type electrode 10 is deposited on the light generation portion, and a n-type electrode 11 is deposited on the light emitting end portion. Next, aback of the n-type InP substrate 1 is polished, thereby taking the thickness of the n-type InP substrate 1 to, for example, 150 μm.

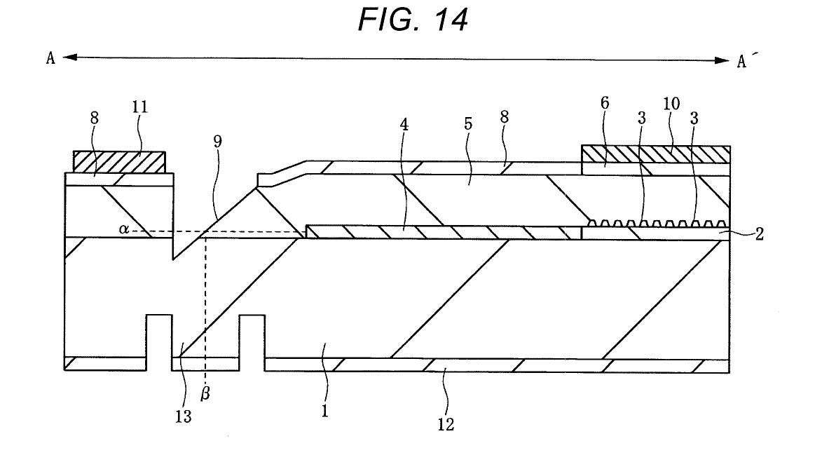

Next, as shown in FIG. 14, a mask 12 formed of the patterned silicon nitride (SiN) film is formed on the back of the n-type InP substrate 1. Next, a part of the n-type InP substrate 1 of the light emitting end portion is dug out in a doughnut form by the reactive ion etching using a mixed gas of methane (CH₄) and hydrogen (H), and for example, a cylinder portion 13 having a diameter of 125 μm and a depth of 30 μm is formed.

At this time, the mask 12 is formed so that a central position of a circle of the cylinder portion 13 intersects with a perpendicular line (β) facing the back of the n-type InP substrate 1 directly beneath an intersecting point between an extension line (α) of the passive waveguide 4 in the optical axial direction and the monolithic integrated mirror 9 (inclined mirror of 45°). In addition, herein, although the cylinder portion 13 has an exact circular form when viewed in a plane, in some cases, an elliptical form may be used depending on the application.

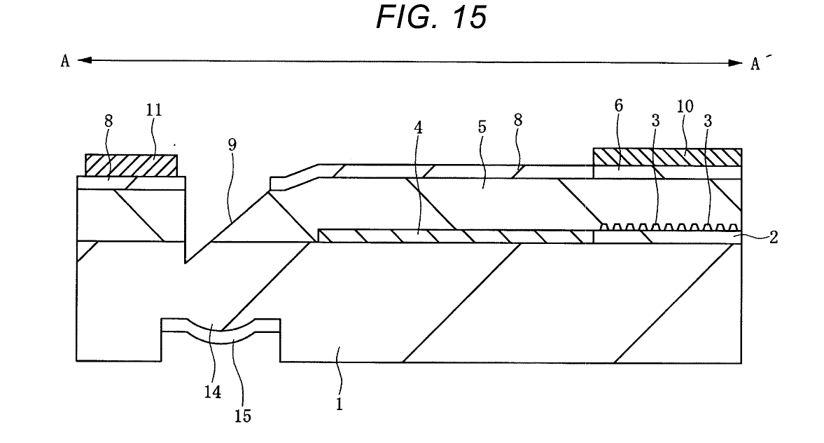

Next, as shown in FIG. 15, after removing the mask 12 on the cylinder portion 13 surrounded by the portion dug out in a doughnut form, the cylinder portion 13 is subjected to the wet etching. Thereby, etching is performed from the surface, the angle of the cylinder portion 13 is smoothened and an InP lens (a monolithic integrated lens) 14 is formed. Next, the surface of the InP lens 14 is covered by the non-reflection film 15. In this manner, since a convex lens is formed on the surface emitting the laser beam, it is possible to obtain a laser beam having a narrow radiation angle and high parallelism. Next, by cleavage of the wafer, an individual bar-shaped laser chip is cut.

After that, although not shown, a high reflective film formed by a stacked structure of amorphous silicon and alumina is formed on a crystal surface exposed by cleavage. After that, chipping is performed for every determined channel.

In Embodiment 1, the diameter of the InP lens 14 is set to, for example, 120 μm, and the curvature of the InP lens 14 is set to, for example, 0.004 μm⁻¹. Furthermore, a distance from the surface of the InP lens 14 to the light emitting point is set to, for example, 160 μm. Furthermore, each laser beam emitted from the passive waveguides 4a, 4b, 4c and 4d is totally reflected in a normal direction to the surface of the n-type InP substrate 1 from the surface side of the n-type InP substrate 1 to the back thereof by the monolithic integrated mirror 9, and is incident to the InP lens 14. At this time, the incident positions of each laser beam are arranged on a straight line in a direction perpendicular to the optical axial direction passing through the center of the InP lens 14, and a design is provided so that two external laser beams are each incident to the position separated from the center of the InP lens 14, for example, by 15 μm, and two internal laser beams are each incident to the position separated from the center of the InP lens 14, for example, by 5 μm.

With this design, the four laser beams are condensed at a position of about 100 μm from the surface of the InP lens 14. At this time, a far-field pattern (FFP) of each laser beam emitted from each channel is about 13° at a full width at half maximum in both of the optical axial direction and a direction perpendicular to the optical axial direction, and an optical spot size at the condensing position is a diameter of about 40 μm.

As a result of carrying out an optical coupling test of 4 wavelengths using the multi-wavelength horizontal resonator surface-emitting type laser and a “graded index (GI) multi-mode fiber (MMF) with a 50 μm core type, by placing the multi-mode fiber (MMF) at the condensing position of light, it was possible to obtain the optical coupling of low loss in which a coupling loss was 0.3 dB or less in the entire channels at the same time. Furthermore, in the entire channels, satisfactory high-speed characteristics reflecting a short resonator structure were shown, and at 85° C., the operation of 25 Gbps was realized in the driving conditions of a bias electric current of 60 mA, and an electric current amplitude of 40 mApp.

In this manner, according to Embodiment 1, it is possible to manufacture the multi-wavelength horizontal resonator surface-emitting type laser capable of multiplexing 4 wavelengths for a next-generation light interconnect by a simple method.

In addition, in Embodiment 1, although an example was shown in which the invention was applied to the InGaAlAs quantum well type laser having the wavelength band of 1.3 μm formed on the n-type InP substrate 1, the substrate material, the active layer material, and the oscillation wavelength are not limited to this example. For example, the invention can also be similarly applied to a material system such as an InGaAsP quantum well type laser having the wavelength band of 1.55 μm.

Furthermore, in the Embodiment 1, although an example was described in which the invention is applied to the ridge waveguide structure, the invention can also be applied to a buried hetero structure (BH structure). That is, a shape of a cross-section of the p-type InP cladding layer 5 in a direction perpendicular to the optical axial direction on the surface of the n-type InP substrate 1 has a convex shape in the thickness direction of the n-type InP substrate 1, and is formed in a stripe shape in the optical axial direction. The stripe shape has a depth reaching the n-type InP substrate 1 beyond the InGaAlAs active layer 2, and both side surfaces of the stripe shape are buried with a semi-insulating semiconductor material.

Module to which Multi-Wavelength Horizontal Resonator Surface-Emitting Type Laser is Applied

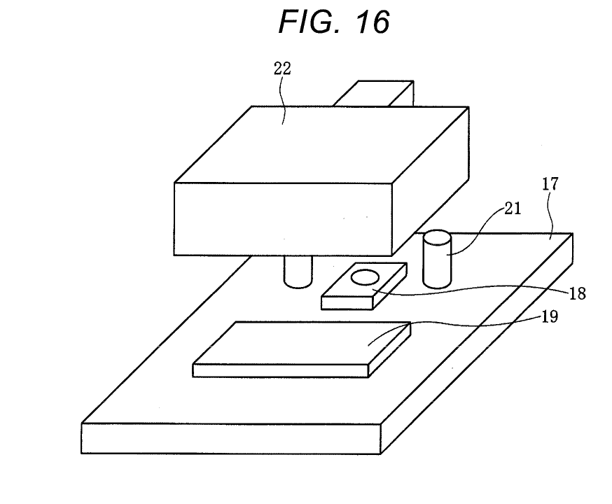

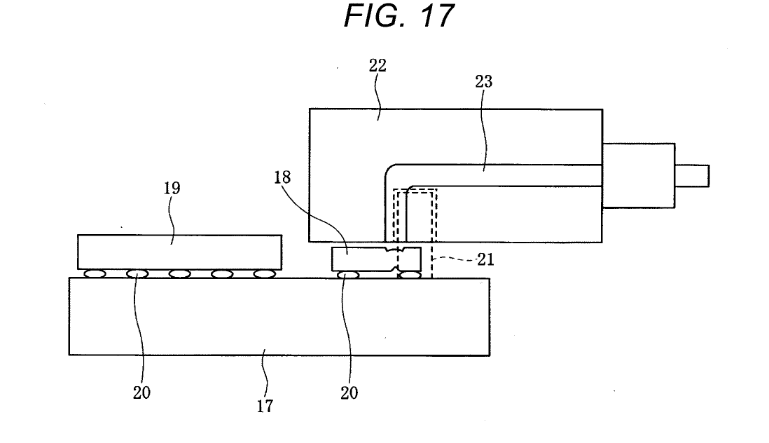

A configuration example of a case of applying the multi-wavelength horizontal resonator surface-emitting type laser according to Embodiment 1 to the module will be described using FIGS. 16 and 17. FIG. 16 is a bird's-eye view of the module. FIG. 17 is a cross-sectional view of major parts of the module along the optical axial direction.

As shown in FIGS. 16 and 17, the module according to Embodiment 1 is configured so that a multi-wavelength horizontal resonator surface-emitting laser chip 18 and an integrated circuit 19 for driving the laser are mounted, while taking electrical connection by a gold bump 20, on a multi-layer wiring ceramic substrate 17 having a strip line. A fiber connector 22 is mounted above the multi-wavelength horizontal resonator surface-emitting laser chip 18 at the position having the optimal optical coupling, by a connector column 21. Four multi-mode fibers (MMF) 23 are mounted inside the fiber connector 22 while being bent by 90°, and one light receiving surface thereof and the light emitting surface of the multi-wavelength horizontal resonator surface-emitting laser chip 18 are mounted at the position having the optimal optical coupling.

The signal of a total of 100 Gbps of 25 Gbps per channel can be transported while performing the wavelength-multiplexing, by the use of this module. In this manner, by the use of the horizontal resonator surface-emitting type laser according to Embodiment 1, it is possible to manufacture the multi-wavelength multiplexing optical module that is suitable for a router device, and has a small size and a low cost.

### Embodiment 2

In Embodiment 2, a horizontal resonator surface-emitting type laser of a direct modulation type of 8 channels (an 8 channel array-type lens integration horizontal resonator surface-emitting laser) will be described as an example.

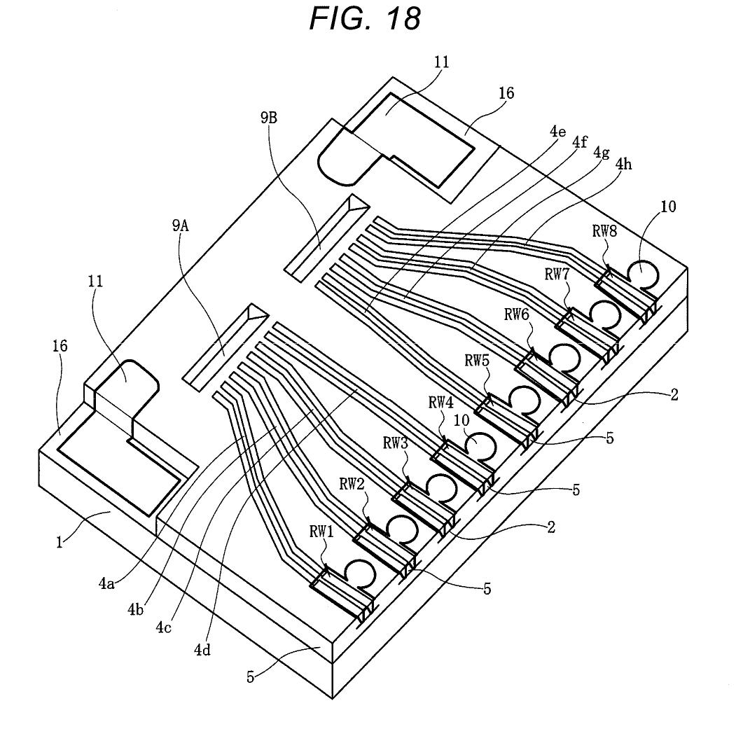

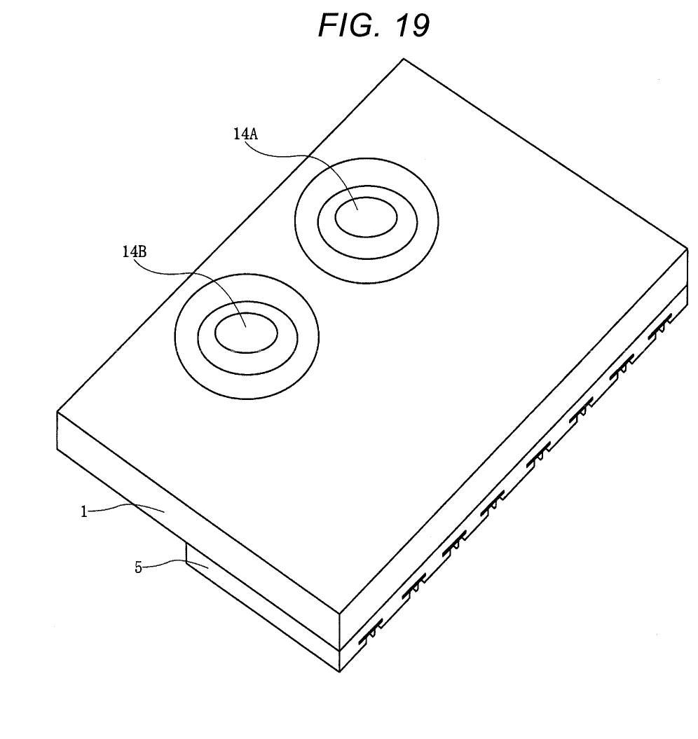

A structure of the multi-wavelength horizontal resonator surface-emitting type laser having the wavelength band of 1.3 μm according to Embodiment 2 will be described using FIGS. 18 and 19. FIG. 18 is a bird's-eye view of a surface side of the multi-wavelength horizontal resonator surface-emitting type laser. FIG. 19 is a bird's-eye view of a light emitting surface side (a back side) of the multi-wavelength horizontal resonator surface-emitting type laser.

A basic structure of each channel is a DFB laser that has the same ridge-type waveguide structure and the high-mesa type passive waveguide as the above-mentioned Embodiment 1. Furthermore, the diffraction grating of each channel is designed so as to oscillate the different wavelengths at the wavelength band of 1.3 μm, respectively, and is a laser of an array structure in which the laser beam of 8 wavelengths is emitted from the laser chip.

The multi-wavelength horizontal resonator surface-emitting type laser according to Embodiment 2 has two monolithic integrated lenses, and it is characterized in that 4 wavelengths of the laser beam of 8 wavelengths enter each of the different monolithic integrated lenses, and the laser beam of 8 wavelengths emitted from two monolithic integrated lenses is condensed on one external point of the laser chip. For example, the length of the laser chip in the optical axial direction is, for example, 800 μm, and the length in a direction perpendicular to the optical axial direction is, for example, 1000 μm.

As shown in FIGS. 18 and 19, the light generation portion (the laser portion) is configured so that the InGaAlAs active layer 2 and the p-type InP cladding layer (the semiconductor buried layer) 5 are sequentially stacked on the n-type InP substrate 1. In addition, a diffraction grating (not shown) is formed directly above the InGaAlAs active layer 2. The ridge-type waveguide structures RW1, RW2, RW3, RW4, RW5, RW6, RW7 and RW8 of each channel are formed by the above-mentioned stacked structure, and the transmission wavelengths of each channel are 1285 nm, 1290 nm, 1295 nm, 1300 nm, 1305 nm, 1310 nm, 1315 nm and 1320 nm.

Furthermore, the respective channels are electrically separated by the separation grooves. The length of the light generation portion (the ridge-type waveguide structures RW1, RW2, RW3, RW4, RW5, RW6, RW7 and RW8) in the optical axial direction is, for example, 150 μm, and a coupling coefficient of the diffraction grating is, for example, 200 cm⁻¹. The ridge-type waveguide structures RW1, RW2, RW3, RW4, RW5, RW6, RW7 and RW8 are butt-joint connected to one of the high-mesa type passive waveguides 4a, 4b, 4c, 4d, 4e, 4f, 4g and 4h in which InGaAsP is used as the waveguide layer, respectively. The lengths of the passive waveguides 4a, 4b, 4c, 4d, 4e, 4f, 4g and 4h in the optical axial direction are, for example, 500 μm.

The laser beam of 4 wavelengths emitted from the passive waveguides 4a, 4b, 4c and 4d is fully reflected in the normal direction to the surface of the n-type InP substrate 1 from the surface side of the n-type InP substrate 1 to the back side thereof by the monolithic integrated mirror (the reflecting mirror) 9A, and is emitted to the InP lens (the monolithic integrated lens) 14A. At this time, the incident positions of each laser beam are arranged on the straight line passing through the centers of the InP lenses 14A and 14B in a direction perpendicular to the optical axial direction, and are placed outside the center of the InP lens 14A at equal intervals. A pitch interval of each channel is, for example, 10 μm, and the curvature of the InP lens 14A is, for example, 0.005 μm⁻¹.

Meanwhile, the laser beam of 4 wavelengths emitted from the passive waveguides 4e, 4f, 4g and 4h is fully reflected in the normal direction to the surface of the n-type InP substrate 1 from the surface side of the n-type InP substrate 1 to the back side thereof by the monolithic integrated mirror (the reflecting mirror) 9B, and is emitted to the InP lens (the monolithic integrated lens) 14B. A positional relationship between the InP lens 14B and each laser beam emitted from the passive waveguides 4e, 4f, 4g and 4h is designed so as to be symmetrical with the positional relationship between the InP lens 14A and each laser beam emitted from the passive waveguides 4a, 4b, 4c, and 4d, with respect to the center of the laser chip.

By designing in this manner, the laser beam of 8 wavelengths is condensed at the position separated from the laser chip by about 100 μm, on an intersection point between the straight line passing through the centers of the InP lenses 14A and 14B in the direction perpendicular to the optical axial direction and the straight line passing through the center of the laser chip in the optical axial direction. Furthermore, a far-field pattern (FFP) of each laser beam is about 10°, and the optical spot size at the condensation position is about 35 μm by a full width at half maximum.

By placing the graded index (GI) multi-mode fiber (MMF) on the condensation position, 8 wavelengths can be directly wavelength-multiplexed on the multi-mode fiber (MMF) from the laser chip. Furthermore, at 85° C. for the entire channels, the operation of 25 Gbps was realized in the driving conditions of a bias electric current of 60 mA and an electric current amplitude of 40 mApp.

In this manner, according to Embodiment 2, the high-speed optical signal of 25 Gbps of 8 wavelengths capable of coping with a router of 100 Tbps can be subjected to the multiple-wavelength transmission by the multi-wavelength horizontal resonator surface-emitting type laser chip having a small and simple configuration.

### Embodiment 3

In Embodiment 3, a horizontal resonator surface emitting-type laser of 4 channels (a lens integration horizontal resonator surface-emitting laser of 4 channel array type) capable of directly performing the wavelength multiplexing of the single mode fiber at high optical coupling efficiency is described as an example. In order to increase the coupling efficiency of the single mode fiber, the diffraction grating glass substrate is hybrid-mounted on the back of the horizontal resonator surface-emitting type laser (the laser chip).

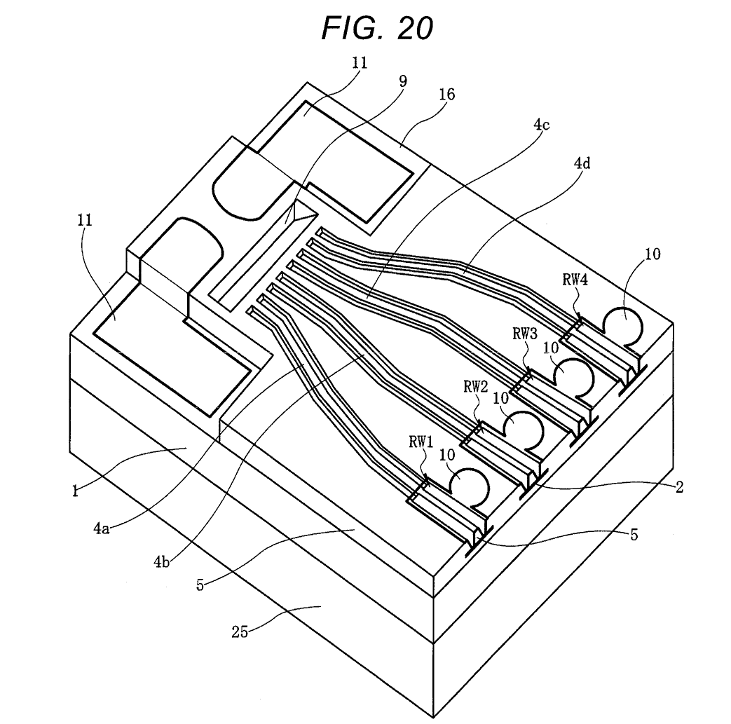

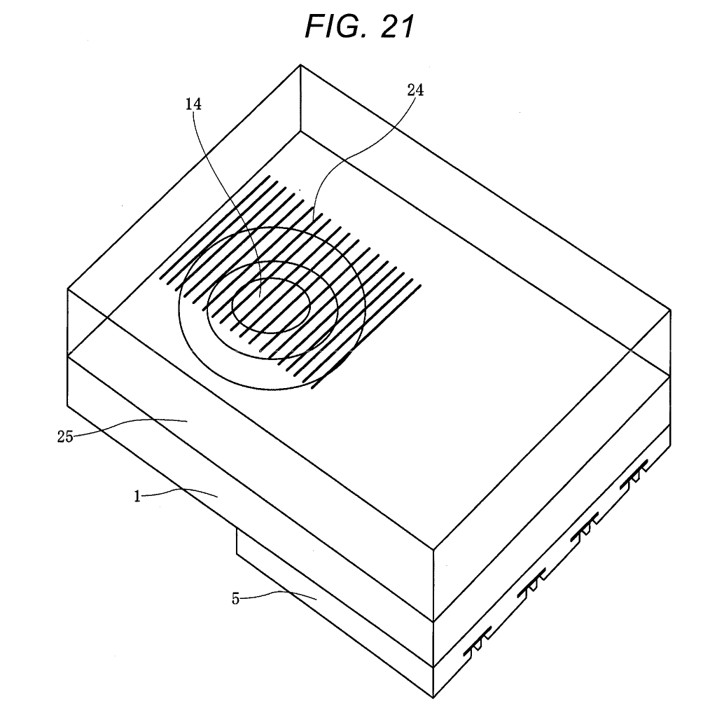

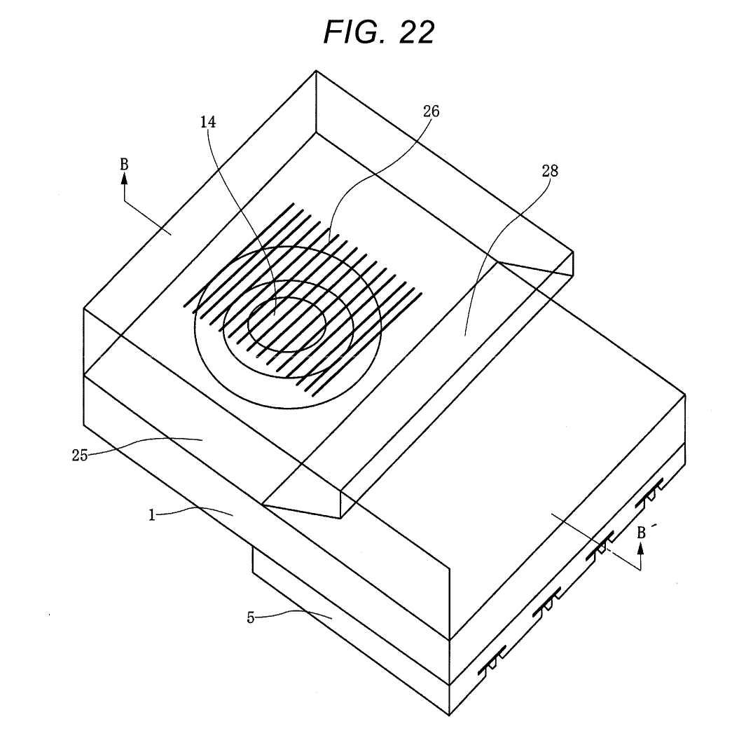

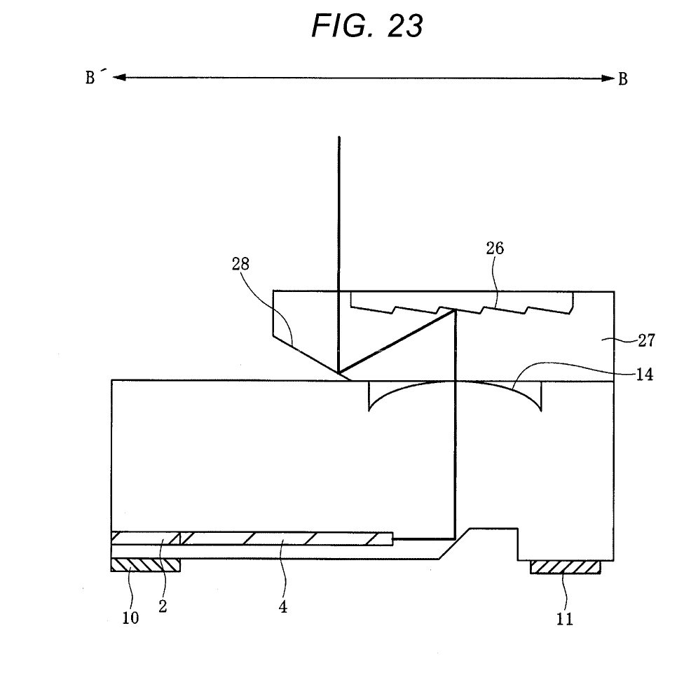

A structure of the multi-wavelength horizontal resonator surface-emitting type laser according to Embodiment 3 will be described using FIGS. 20 to 23. FIG. 20 is a bird's-eye view of the surface side of the multi-wavelength horizontal resonator surface-emitting type laser that uses a transmission type diffraction grating. FIG. 21 is a bird's-eye view of the light emitting surface side (the back side) of the multi-wavelength horizontal resonator surface-emitting type laser that uses the transmission type diffraction grating. FIG. 22 is a bird's-eye view of the light emitting surface side (the back side) of the multi-wavelength horizontal resonator surface-emitting type laser that uses the reflection type diffraction grating. FIG. 23 is a cross-sectional view of major parts (a cross-sectional view of major parts along line B-B′ of FIG. 22) along the optical axial direction of the multi-wavelength horizontal resonator surface-emitting type laser that uses the reflection type diffraction grating.

Generally, when condensing the plurality of laser beams on the single mode fiber, theoretical loss occurs depending on the number of wavelengths. In the case of 4 wavelengths, a loss of 6 dB per wavelength occurs. In order to solve this problem, in Embodiment 3, the reduction of the coupling loss is promoted by the use of the interference action in the wavelength multiplexing action of a 4 wavelength horizontal resonator surface emitting-type laser.

FIGS. 20 and 21 are examples that use a transmission type diffraction grating. The thickness of the glass substrate 25 is adjusted so that the position of the diffraction grating 24 becomes a position where the laser beam of 4 wavelengths emitted from the InP lens (the monolithic integrated lens) 14 is condensed. By taking such a configuration, the wavelength multiplexing can be directly performed, while suppressing the loss of each channel of the single mode fiber to 3 dB.

Furthermore, when raising the dispersion by higher-order diffraction, it is advantageous to use the reflection type diffraction grating in view of the efficiency. As shown in FIGS. 22 and 23, the laser beam of 4 wavelengths emitted from the laser chip is condensed on one point by the InP lens 14, and is reflected by the reflection type diffraction grating 26. Moreover, the laser beam is reflected by a reflection surface 28 formed by machining a glass substrate 27 again and is emitted to the outside. With such a configuration, the laser beam subjected to the wavelength multiplexing is coupled to the single mode fiber at high coupling efficiency, and thus the loss of each channel can be suppressed to 2 dB.

In this manner, according to Embodiment 3, the plurality of wavelengths can be effectively coupled to the single mode fiber, and can be subjected to the wavelength multiplexing.

### Embodiment 4

In Embodiment 4, a horizontal resonator surface-emitting type laser chip of 4 channels of a modulator integration type (a lens integration horizontal resonator surface-emitting laser of 4 channel array type) will be described as an example.

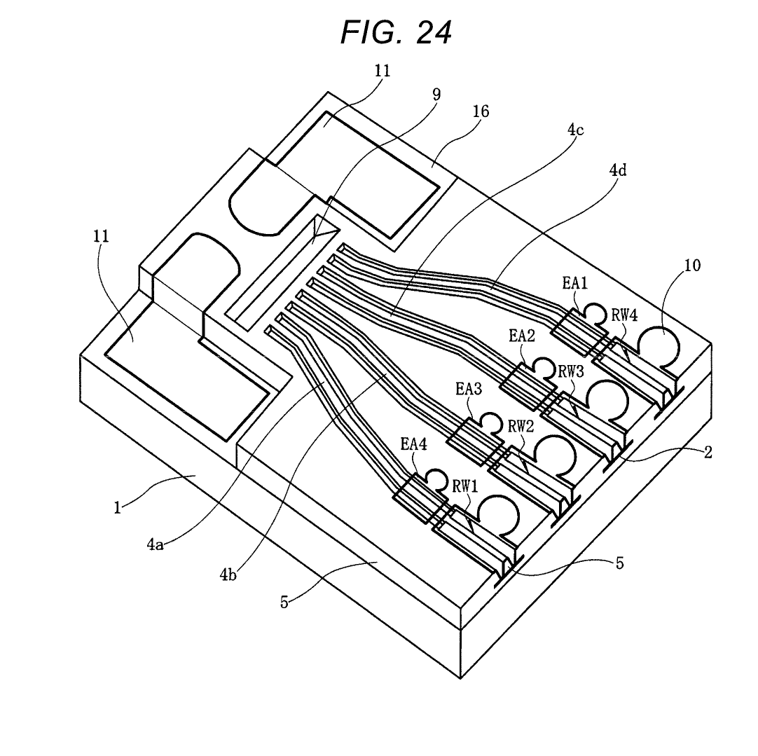

A structure of the multi-wavelength horizontal resonator surface-emitting type laser according to Embodiment 4 will be described using FIG. 24. FIG. 24 is a bird's-eye view of the surface side of the multi-wavelength horizontal resonator surface-emitting type laser of the modulator integration type.

For example, the manufacturing method of the multi-wavelength horizontal resonator surface-emitting type laser of the modulator integration type is as follows. First, the InGaAlAs active layer 2 is formed on the n-type InP substrate 1 using an MOCVD method. Next, after the InGaAlAs active layer 2 other than the light generation portion (the laser portion) is selectively removed, the passive waveguide layer is formed using the MOCVD method. After that, like the above-mentioned Embodiment 1, ridge-type waveguide structures RW1, RW2, RW3, and RW4, ridge-type electric field absorbing-type modulator portions EA1, EA2, EA3 and EA4, and high-mesa type passive waveguides 4a, 4b, 4c and 4d are each formed. A length of the light generation portion in the optical axial direction is, for example, 300 μm, and the lengths of the electric field absorbing type modulator portions EA1, EA2, EA3 and EA4 in the optical axial direction are, for example, 100 μm. The structures of the passive waveguides 4a, 4b, 4c and 4d are the same as those of the above-mentioned Embodiment 1. Furthermore, the transmission wavelength of each channel, the design of the InP lens (the monolithic integrated lens) 14, the emission position of each laser beam and the like are the same as those of the above-mentioned Embodiment 1. A length of the laser chip in the optical axial direction is, for example, 1050 μm, and a length in a direction perpendicular to the optical axial direction is, for example, 500 μm. Furthermore, the far-field pattern (FFP) of each laser beam emitted from each channel, and the condensation position are the same as those of the above-mentioned Embodiment 1.

In this manner, according to Embodiment 4, in the multi-wavelength horizontal resonator surface-emitting type laser of the modulator integration type, the multiple-wavelength transmission can also be performed by a small and simple structure.

### Embodiment 5

In Embodiment 5, a horizontal resonator surface-emitting type laser of 4 channels (a lens integration horizontal resonator surface-emitting laser of 4 channel array type) constituted by two pairs of ridge-type waveguide structures and two pairs of high-mesa type passive waveguides will be described as an example.

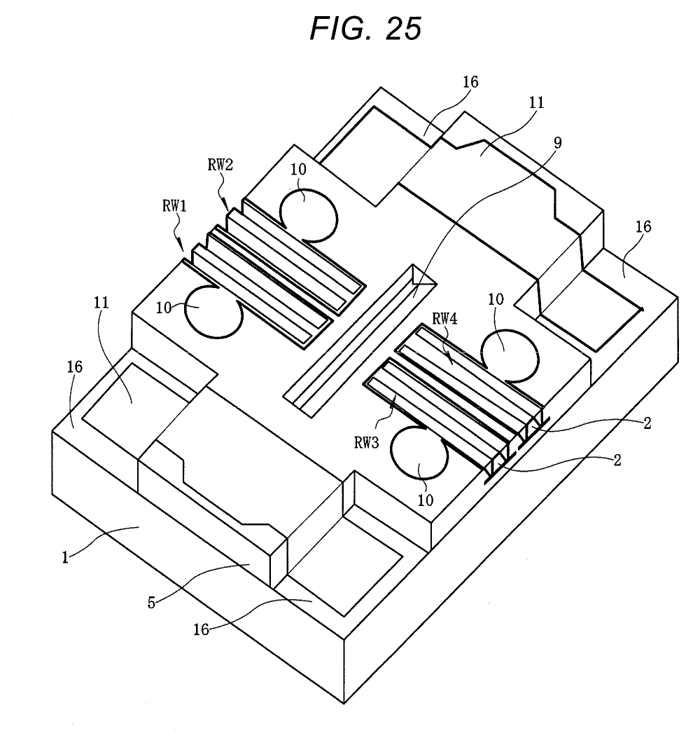

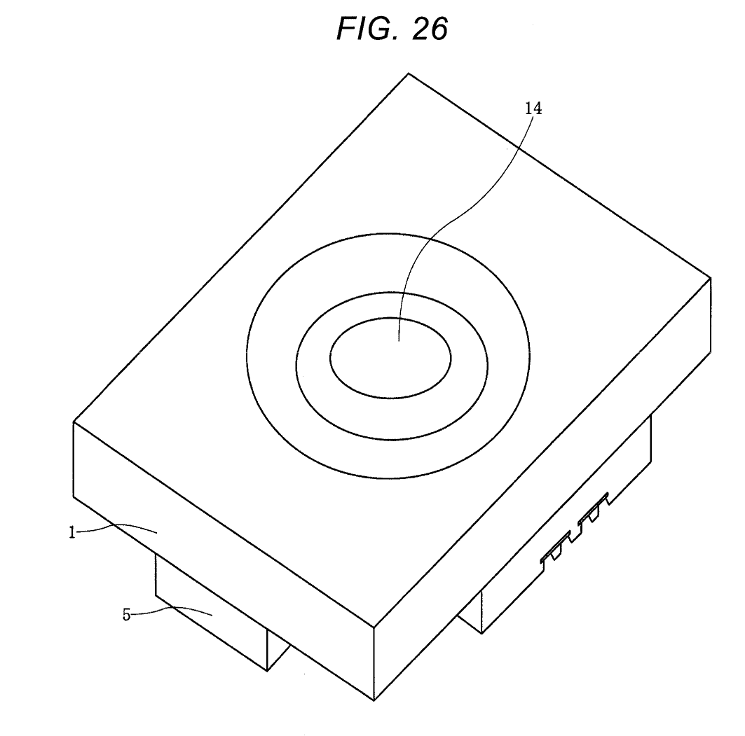

A structure of the multi-wavelength horizontal resonator surface-emitting type laser according to Embodiment 5 will be described using FIGS. 25 and 26. FIG. 25 is a bird's-eye view of the surface side of the multi-wavelength horizontal resonator surface-emitting type laser using the transmission type diffraction grating. FIG. 26 is a bird's-eye view of the light emitting surface side (the back side) of the multi-wavelength horizontal resonator surface-emitting type laser using the transmission type diffraction grating.

As shown in FIGS. 25 and 26, the InP lens (the monolithic integrated lens) 14 is formed substantially in the central portion of the n-type InP substrate 1. The two pairs of ridge-type waveguide structures RW1 and RW2 formed on the n-type InP substrate 1 face two pairs of ridge-type waveguide structures RW3 and RW4 similarly formed on the n-type InP substrate 1 via the InP lens 14. Furthermore, the InP lens 14 is configured so that a cross-sectional shape thereof in the optical axial direction is tapered, and thus it is possible to reflect the laser beam generated from the ridge-type waveguide structures RW1 and RW2 placed to face each other and the laser beam generated from the ridge-type waveguide structures RW3 and RW4 from the surface side of the n-type InP substrate 1 to the back side thereof in the normal direction to the surface of the n-type InP substrate 1.

Furthermore, in the multi-wavelength horizontal resonator surface-emitting type laser according to Embodiment 5, a pad portion of the p-type electrode 10 is placed outside each channel (a laser stripe) of the ridge-type waveguide structures RW1 and RW2 and outside each channel (the laser stripe) of the ridge-type waveguide structures RW3 and RW4. Thereby, for example, compared to a case of the multi-wavelength horizontal resonator surface-emitting type laser according to the above-mentioned Embodiment 1, the pitch interval between the adjacent channels (the laser stripes) can be reduced.

With such a configuration, there is no need for a passive waveguide, the pitch interval of each channel (the laser stripe) of the ridge-type waveguide structures RW1 and RW2 and the pitch interval of each channel (the laser stripe) of the ridge-type waveguide structures RW3 and RW4 can be set to suitable pitch intervals, and thus the laser chip can be reduced in size. Furthermore, the process of forming the passive waveguide can be omitted, and the simplification of manufacturing the laser chip and cost reduction can be realized.

Furthermore, the n-type contact layers 16 are placed on four locations of outside both of the ridge-type waveguide structures RW1 and RW2 and outside both of the ridge-type waveguide structures RW3 and RW4, and n-type electrodes 11 are placed on two locations of outside both of the ridge-type waveguide structures RW1 and RW2 and the ridge-type waveguide structures RW3 and RW4.

The structure of the light generation portion (the laser portion) is the same as the above-mentioned Embodiment 1, and the pitch of the diffraction grating of each channel is adjusted so that the wavelengths of the laser beams generated from the ridge-type waveguide structures RW1, RW2, RW3 and RW4 each become 1295 nm, 1300 n, 1305 nm and 1310 nm.

The length of the laser chip in the optical axial direction is, for example, 400 μm, and the length in the direction perpendicular to the optical axial direction is, for example, 600 μm. The diameter of the InP lens (the monolithic integrated lens) 14 is, for example, 150 μm, and the curvature of the InP lens 14 is, for example, 0.006 μm. Furthermore, the positions of the laser beam incident from each channel are placed so as to be arranged symmetrically, for example, at a position of 10 μm from the center of the InP lens 14.

With this design, four laser beams emitted from the InP lens 14 are condensed at a position separated from the laser chip (the surface of the InP lens 14) by about 100 μm at the intersection point between the straight line passing through the center of the InP lens 14 in the direction perpendicular to the optical axial direction and the straight line passing through the center of the laser chip in the optical axial direction. Furthermore, the far-field pattern (FFP) of each laser light emitted from each channel is about 10°, and the optical spot size at the condensation position is about 35 μm by a full width at half maximum.

By placing the graded index (GI) multi-mode fiber (MMF) at this condensation position, the 4 wavelengths can be directly subjected to the wavelength multiplexing to the multi-mode fiber (MMF) from the laser chip. Furthermore, at 85° C. for the entire channels, the operation of 25 Gbps was realized in the driving conditions of a bias electric current of 60 mA, and an electric current amplitude of 40 mApp.

Furthermore, like the above-mentioned Embodiment 3, the transmission type diffraction grating or the reflection type diffraction grating may be provided on the back side (the InP lens 14 side) of the laser chip.

In addition, in the multi-wavelength horizontal resonator surface-emitting type laser according to Embodiment 5, the same passive waveguide as the passive waveguide described in the above-mentioned Embodiment 1 may also be formed.

In this manner, according to Embodiment 5, it is possible to perform the multiple-wavelength transmission of the high-speed optical signal of 25 Gbps of 4 wavelengths capable of coping with the router of 100 Tbps, by the use of the laser chip having a small and simple configuration.

Although the invention has been specifically described by the inventors based on the embodiments, it is needless to say that the invention is not limited to the above-mentioned embodiments, but can be variously changed within the scope that does not depart from the gist thereof.

The invention can be applied to the semiconductor laser element used for optical communication, and the optical communication module using the same.

What is claimed is:

1. A semiconductor laser device comprising:
a semiconductor substrate of a first conductivity type;
a plurality of active layers formed on a first surface of the semiconductor substrate;
a plurality of cladding layers of a second conductivity type different from the first conductivity type provided on each of the active layers;
a plurality of resonator portions that resonate light generated in each of the active layers;
a reflecting mirror that is provided on the first surface of the semiconductor substrate, and reflects the light generated in the plurality of the active layers to a second surface side facing the first surface; and
a condenser lens that is formed on the second surface and collects the light reflected by the reflecting mirror,
wherein wavelengths of the light generated in the plurality of active layers are different from each other, and
all of emission positions on the condenser lens of the light generated in the plurality of active layers deviate from a center of the condenser lens.

2. The semiconductor laser device according to claim 1,
wherein a light generation portion configured to discharge the light generated in the active layers to the reflecting mirror is a distributed feedback laser.

3. The semiconductor laser device according to claim 1,
wherein the light generation portion configured to discharge the light generated in the active layers to the reflecting mirror is a distributed Bragg reflection type laser.

4. The semiconductor laser device according to claim 1,
wherein the light generation portion configured to discharge the light generated in the active layers to the reflecting mirror has
a ridge waveguide structure in which a shape of a cross-section of the cladding layer in a direction perpendicular to an advancing direction of the light on the first surface of the semiconductor substrate is machined in a convex shape in a thickness direction of the semiconductor substrate.

5. The semiconductor laser device according to claim 1,
wherein the light generation portion configured to discharge the light generated in the active layers has
a buried hetero structure in which the active layers and the semiconductor substrate are machined in a stripe shape along the advancing direction of the light, the stripe shape has a depth reaching the semiconductor substrate beyond the active layers, and both side surfaces of the stripe shape are buried with a semi-insulating semiconductor material.

6. The semiconductor laser device according to claim 1, further comprising:
a plurality of waveguides that guides the beams of light each generated in the plurality of active layers to the reflecting mirror,
wherein the plurality of waveguides is a waveguide that is grown by embedding a bulk semiconductor.

7. The semiconductor laser device according to claim 1, further comprising:
a plurality of waveguides that guides the beams of light each generated in the plurality of active layers to the reflecting mirror,
wherein the plurality of waveguides is a high-mesa type waveguide which includes a multiple quantum well structure formed by stacking a plurality of semiconductor layers of two types or more, and the cladding layer formed on the multiple quantum well structure, and in which a shape of a cross-section perpendicular to the advancing direction of the light is machined in a convex form, and depths of both sides of the convex form reach a part of the semiconductor substrate beyond the multiple quantum well structure.

8. The semiconductor laser device according to claim 1,
wherein two reflecting mirrors are formed, the beams of light each generated in a part of the plurality of active layers are incident to one reflecting mirror, and the beams of light each generated in other parts of the plurality of active layers are incident to the other reflecting mirror.

9. The semiconductor laser device according to claim 1,
wherein a glass substrate formed with a transmission type diffraction grating is placed on a light emitting side of the condenser lens.

10. The semiconductor laser device according to claim 1,
wherein a reflection type diffraction grating, and a glass substrate formed with a reflection surface for reflecting the light reflected from the reflection type diffraction grating again are placed on the light emitting side of the condenser lens.

11. The semiconductor laser device according to claim 1, further comprising:
a plurality of waveguides that waveguides the beams of light each generated in the plurality of active layers to the reflecting mirror,
wherein a modulator configured to modulate the beams of light each generated in the plurality of active layers is formed in a part of each of the upper side of the plurality of waveguides.

12. A semiconductor laser device comprising: a semiconductor substrate of a first conductivity type that has a surface and a back of an opposite side to the surface, a plurality of first light generation portions; a plurality of second light generation portions, and a light emitting end portion placed between the plurality of first light generation portions and the plurality of second light generation portions,
wherein each of the plurality of first light generation portions and each of the plurality of second light generation portions include
an active layer formed on the surface of the semiconductor substrate,
a cladding layer of a second conductivity type different from the first conductivity type provided on the active layer, and
a resonator portion that reflects or resonates the light in an advancing direction of the light,
the light emitting end portion includes
a reflecting mirror that is formed on the surface side of the semiconductor substrate to emit beams of light each generated in the plurality of first light generation portions and beams of light each generated in the plurality of second light generation portions from the surface side of the semiconductor substrate to the back side in a normal direction to the surface, and
a condenser lens provided on the back of the semiconductor substrate,
wavelengths of the beams of light each generated in the plurality of first light generation portions and the plurality of second light generation portions are different from each other, and
the beams of light each generated in the plurality of first light generation portions and the beams of light each generated in the plurality of second light generation portions are reflected by the reflecting mirror and are incident to the condenser lens, and emission positions on the condenser lens of the beams of light each generated in the plurality of first light generation portions and the beams of light each generated in the plurality of second light generation portions deviate from a central position of the condenser lens.

13. The semiconductor laser device according to claim 12,
wherein the plurality of first light generation portions and the plurality of second light generation portions are distributed feedback lasers.

14. The semiconductor laser device according to claim 12,
wherein the plurality of first light generation portions and the plurality of second light generation portions are distributed Bragg reflection type lasers.

15. The semiconductor laser device according to claim 12,
wherein the plurality of first light generation portions and the plurality of second light generation portions have a ridge waveguide structure in which a shape of a cross-section of the cladding layer in a direction perpendicular to an advancing direction of the light on the surface of the semiconductor substrate is machined in a convex shape in a thickness direction of the semiconductor substrate.

16. The semiconductor laser device according to claim 12,
wherein the plurality of first light generation portions and the plurality of second light generation portions have a buried hetero structure in which the active layers and the semiconductor substrate are machined in a stripe shape along the advancing direction of the light, the stripe shape has a depth reaching the semiconductor substrate beyond the active layers, and both side surfaces of the stripe shape are buried with a semi-insulating semiconductor material.

17. The semiconductor laser device according to claim 12, further comprising:
a plurality of waveguides that waveguides the beams of light each generated in the plurality of first light generation portions and the plurality of second light generation portions to the reflecting mirror,
wherein the plurality of waveguides is a waveguide that is grown by embedding a bulk semiconductor.

18. The semiconductor laser device according to claim 12, further comprising:
a plurality of waveguides that waveguides the beams of light each generated in the plurality of first light generation portions and the plurality of second light generation portions to the reflecting mirror,
wherein the plurality of waveguides is a high-mesa type waveguide which includes a multiple quantum well structure formed by stacking a plurality of semiconductor layers of two types or more, and the cladding layer formed on the multiple quantum well structure, and in which a shape of a cross-section perpendicular to the advancing direction of the light is machined in a convex form, and depths of both sides of the convex form reach a part of the semiconductor substrate beyond the multiple quantum well structure.

19. The semiconductor laser device according to claim 12,
wherein a glass substrate formed with a transmission type diffraction grating is placed on a light emitting side of the condenser lens.

20. The semiconductor laser device according to claim 12,
wherein a reflection type diffraction grating, and a glass substrate formed with a reflection surface for reflecting the light reflected from the reflection type diffraction grating again are placed on the light emitting side of the condenser lens.
